(19) United States
(12) Patent Application Publication
(10) Pub. No.: US 2008/0054343 A1
(43) Pub. Date: Mar. 6, 2008

(54) Semiconductor Device and Method for Fabricating the Same

(76) Inventor: Sang Il Hwang, Wonju-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/849,151

(22) Filed: Aug. 31, 2007

(30) Foreign Application Priority Data
Aug. 31, 2006 (KR) 10-2006-0083867

(51) Int. Cl. H01L 29/788; H01L 21/3205

(52) U.S. Cl. 257/321; 438/594; 257/E29.3; 257/E21.294

(57) ABSTRACT

A semiconductor device and methods of fabricating the same are provided. The semiconductor device can include a tunnel oxide layer on a semiconductor substrate, a floating gate having a top surface with concave-convex shapes on the tunnel oxide layer, an ONO (oxide/nitride/oxide) layer on the floating gate, and a control gate on the ONO layer.

### CROSS-REFERENCE TO RELATED APPLICATION

The present application claims the benefit under 35 U.S.C. § 119 of Korean Patent Application No. 10-2006-0083867, filed Aug. 31, 2006, which is hereby incorporated by reference in its entirety.

### BACKGROUND

In a semiconductor device, an important parameter that determines the performance of memory cells utilizing a floating gate and a control gate is a gate coupling coefficient. The gate coupling coefficient has a primary effect on the potential of the floating gate. A higher gate coupling coefficient brings the potential of the floating gate closer to that of the control gate for any given potential on the control gate of the memory cell. The closer the potential on the floating gate to that of the control gate for a given control gate bias, the better the performance of the memory cell, including higher program and erase efficiency and read current. A higher gate coupling ratio also allows a lowering of operation voltages of memory cells simplifying flash chip design, especially for lower power supply voltages.

The primary factor that determines the gate coupling coefficient is the inter-polysilicon capacitance with respect to the tunnel oxide capacitance. The gate coupling coefficient increases as the inter-polysilicon capacitance increases, and as tunnel oxide capacitance decreases. Tunnel oxide capacitance is determined by a tunnel oxide thickness which is selected based on a minimum thickness providing maximum read current and yet assuring charge retention characteristics, and can not be independently scaled. An example of a tunnel oxide thickness in flash cell is about 90-95 angstroms. The inter-polysilicon capacitance can be increased by increasing the inter-polysilicon capacitor surface area or by reducing the thickness of an ONO (oxide/nitride/oxide) layer formed between the floating gate and control gate stack. FIG. 2 illustrates a typical gate stack. However, the thickness of the ONO layer cannot be reduced much, because the ability of the floating gate to retain charge carriers is reduced as the ONO layer thickness is reduced. Typically, in non-volatile technologies such as flash, the thickness of the ONO layer is reduced to at or near its minimum possible value beyond which charge retention in the floating gate may be compromised.

The gate coupling coefficient can also be increased by increasing the ratio of the surface area of the inter-polysilicon capacitor with respect to a tunnel oxide surface area. An ONO capacitor surface area is determined by the full width of a polysilicon layer 12 including a cell active width and where the polysilicon layer 12 overlaps STI (shallow trench isolation) regions 11A-11B, and the sidewalls of the polysilicon layer 12 as shown in FIG. 1. A tunnel oxide capacitor surface area is determined by the cell active width. Thus, the gate coupling can be increased by increasing the overlap between a poly1 (layer 12) and an isolation layer. This would require increasing isolation spacing (isolation size) to resolve poly1-to-poly1 spacing. However, increasing isolation spacing results in a larger cell size. In fact, the general trend of reducing cell size has resulted in reduction in the active cell width of flash memory transistors through reduction in isolation spacing and polysilicon 12 to the STIs 11A-11B overlap.

The smaller polysilicon to STI overlap reduces the gate coupling coefficient and as a consequence, adversely effects the performance of the memory cell including program and erase efficiency and read speed. Thus, scaling down the size of the memory cell transistors limits the ability to enhance cell performance in conventional technologies.

Accordingly, it would be desirable to provide a cell structure and method for forming the same to enhance the gate coupling coefficient of non-volatile memory transistors that allows the size of the transistors to be reduced without compromising the performance of the memory chip.

### BRIEF SUMMARY

Embodiments of the present invention provide a semiconductor device and a method for fabricating the same, capable of improving the characteristics of the semiconductor device when the semiconductor device is fabricated in a small size. An embodiment provides improved characteristics by increasing a control-floating gate coupling coefficient.

According to an embodiment, a semiconductor device includes a tunnel oxide layer on a semiconductor substrate, a floating gate having a top surface with concave-convex shapes on the tunnel oxide layer, an ONO layer on the floating gate, and a control gate on the ONO layer.

According to an embodiment, a method for fabricating a semiconductor device includes forming a tunnel oxide layer on a semiconductor substrate, forming a floating gate by coating polysilicon and photoresist on the tunnel oxide layer and etching the resultant structure, performing an under ashing process with respect to the photoresist such that a residue remains in an upper portion of the floating gate, performing a blank etching process by using the residue as a mask to form concave-convex shapes in a top surface of the floating gate, depositing an ONO layer on the floating gate, and forming a control gate on the ONO layer.

According to another embodiment, a method for fabricating a semiconductor device includes forming a tunnel oxide layer on a semiconductor substrate, forming a floating gate layer on the tunnel oxide layer and performing a blank etching process with respect to a resultant structure to partially damage a top surface of the floating gate layer and form a residue on an upper portion of the floating gate layer, performing a wet etching process and a washing process with respect to a resultant structure, thereby forming concave-convex shapes in the top surface of the floating gate layer, patterning the floating gate layer to form a floating gate, and depositing an ONO layer on the floating gate, and forming a control gate on the ONO layer.

### BRIEF DESCRIPTION OF THE DRAWINGS

FIGS. 1 and 2 are cross-sectional views showing the structure of a related semiconductor device.

FIGS. 3 to 7 are views showing a method for fabricating a semiconductor device according to an embodiment of the present invention.

FIGS. 8 to 12 are views showing a method for fabricating a semiconductor device according to another embodiment of the present invention.

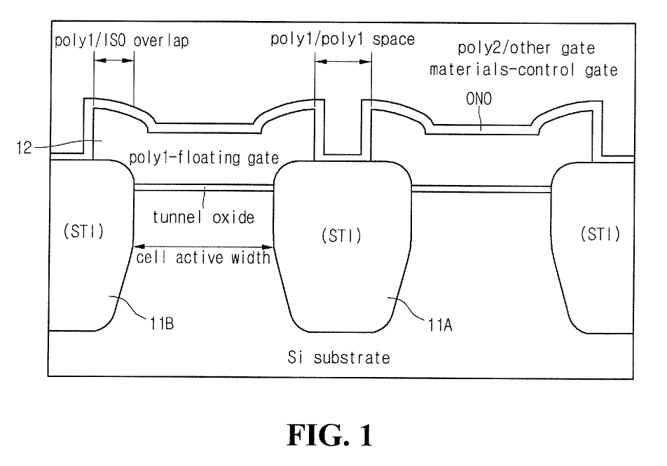

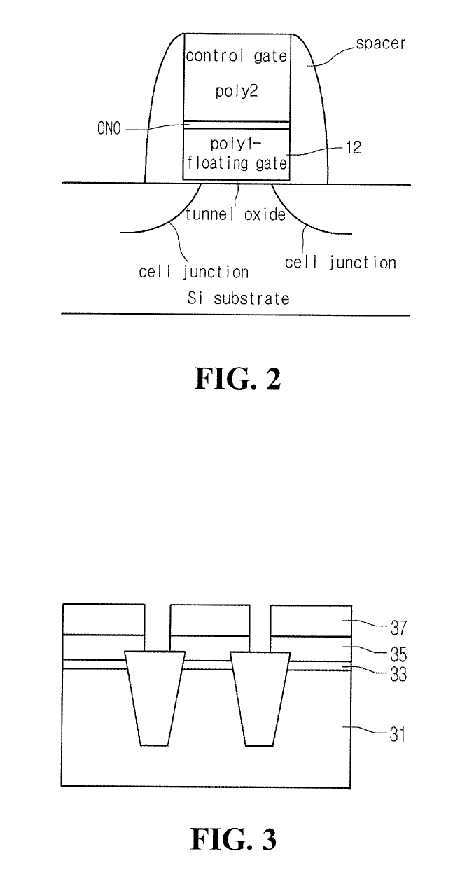

### DETAILED DESCRIPTION

In the description of the embodiment, it will be understood that, when a layer (or film), a region, a pattern, or a structure is referred to as being “on/above” or “under/below” another substrate, another layer (or film), another region, another pad, or another pattern, it can be directly on the other substrate, layer (or film), region, pad, or pattern, or intervening layers may also be present. Furthermore, it will be understood that, when a layer (or film), a region, a pattern, a pad, or a structure is referred to as being “between” two layers (or films), regions, pads, or patterns, it can be the only layer between the two layers (or films), regions, pads, or patterns, or one or more intervening layers may also be present. Thus, it should be determined by the technical idea of the invention.

A non-volatile memory cell that has increased control-to-floating gate coupling coefficients due to a non-uniform gate surface area is provided. In memory transistors according to embodiments of the present invention, the floating gate is formed with a non-flat, non-uniform surface, which significantly increases the surface area interface between the floating gate and the inter-gate dielectric as well as the surface area interface between the inter-gate dielectric and the control gate. As a result, the inter-gate capacitance and the gate coupling coefficient are significantly increased. A high gate coupling coefficient allows the creation of small sized memory cells that have high program and erase efficiency and read speed. Memory cells in accordance with embodiments of the present invention can include flash memory cells, EEPROM cells, and any type of non-volatile memory cell with floating gate.

Referring to FIGS. 3 to 7, in a method for fabricating a semiconductor device, the surface of the floating gate is made rough by partially etching the surface of the floating gate. As a result, a semiconductor device having a high coupling coefficient can be manufactured.

According to an embodiment, as shown in FIG. 3, a tunnel oxide 33 can be formed on a semiconductor substrate 31. Then, polysilicon and photoresist 37 can be coated on the tunnel oxide layer 33 and etched to form a floating gate 35.

The floating gate 35 may be etched through a reactive ion etching (RIE) scheme. Alternatively, the floating gate 35 may be formed through a BCM (By-product Capping Mask) process. The BCM process involves etching a first layer using a photoresist mask and then using by-products produced in the first layer etch as a mask for etching a second layer. The by-products can form on sidewalls of the photoresist mask. A RIE scheme can then be used to etch the second layer using the photoresist having by-products on its sidewalls as an etch mask. In one embodiment, the first layer is BARC (bottom anti-reflective coating layer) and the second layer is polysilicon.

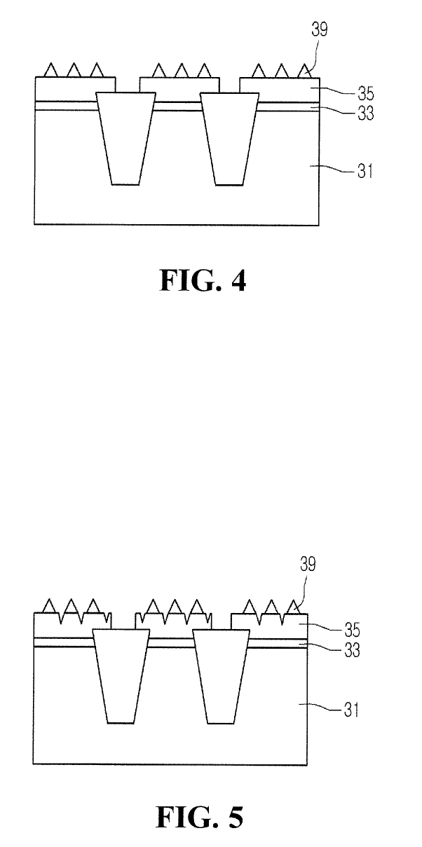

Thereafter, as shown in FIG. 4, an under ashing process can be performed with respect to the photoresist 37 such that residue 39 remains at the upper portion of the floating gate 35. Through the under ashing process, the residue of the photoresist and polymer residue generated in the etching process may remain on an top surface of the floating gate 35.

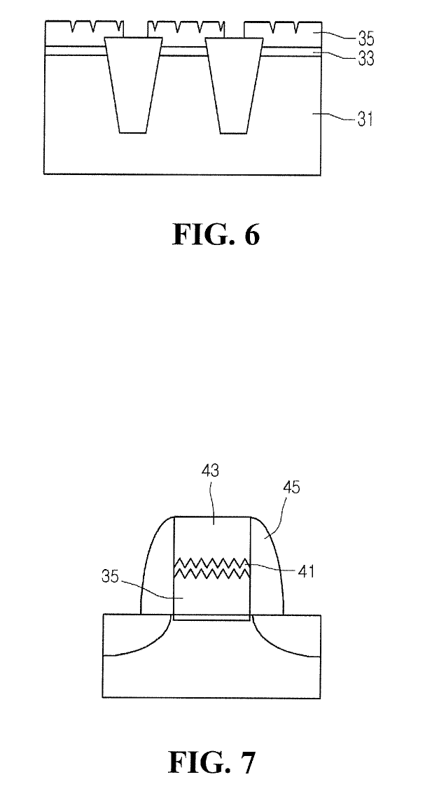

Then, referring to FIGS. 5 and 6, a blank etching process is performed by using the residue 39 as a mask to form concave-convex shapes in the top surface of the floating gate 35. The concave-convex shape provides the floating gate 35 with a rough top surface. The concave-convex surface does not require specific concave and convex forms. Rather, the concave-convex shape involves recessed and protruded forms. The recessed and protruded forms can form a rough pattern.

Thereafter, referring to FIG. 7, an ONO layer 41 and a control gate 43 are formed on the floating gate 35. Then, spacers 45 are formed at the sidewalls of the control gate 43, the ONO layer 41, and the floating gate 35.

The ONO layer 41 may be formed through a deposition scheme. Accordingly, the top and bottom surfaces of the ONO layer 41 may be formed in the concave-convex shape following the shape of the floating gate 35. In addition, the control gate 43 may be formed through a deposition scheme, and the bottom surface of the control gate 43 may be formed in the concave-convex shape. Accordingly, the surface area of the ONO layer may be widened.

The semiconductor device obtained through such a method for fabricating a semiconductor device includes the tunnel oxide layer 33 formed on the semiconductor substrate 31, the floating gate 35 formed on the tunnel oxide layer 33 and having a concave-convex top surface, the ONO layer 41 formed on the floating gate layer 35, and the control gate 43 formed on the ONO layer 41.

A control-floating gate coupling coefficient is increased in the semiconductor device having the above structure, so that the semiconductor device can be manufactured in a small sized, and device characteristics thereof can be improved.

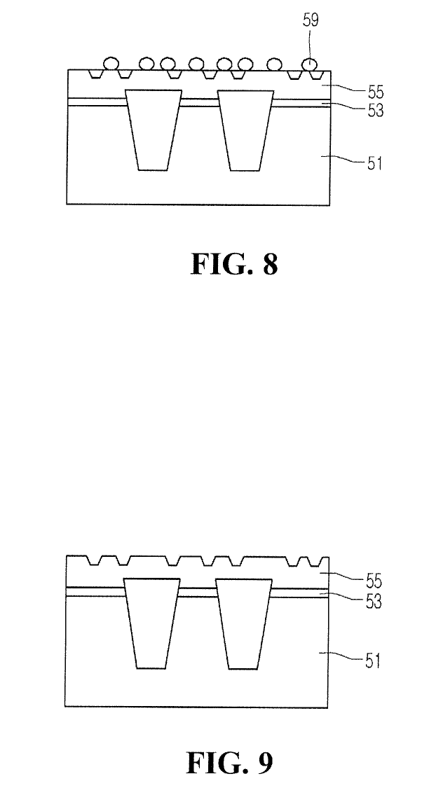

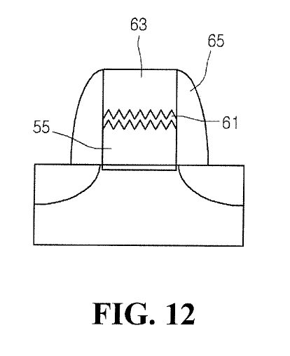

Meanwhile, FIGS. 8 to 12 are views showing a method for fabricating a semiconductor device according to another embodiment.

Referring to FIGS. 8 to 12, the surface of the polysilicon for the floating gate can be partially subject to a wet etching process to make the surface of the floating gate rough. Accordingly, the semiconductor device having a high coupling coefficient may be manufactured.

In a method for fabricating a semiconductor device according to an embodiment as shown in FIG. 8, a tunnel oxide layer 53 can be formed on a semiconductor substrate 51. A material for a floating gate 55 can be formed on the tunnel oxide layer 53, and a blank etching process can be performed with respect to the resultant structure such that a portion of the top surface of the material for the floating gate 55 is damaged, and a residue is formed on the floating gate 55. The material for the floating gate 55 may be etched through an RIE etching process, and the residue 59 may be polymer. The polymer may be a by-product created through the etching process.

Subsequently, referring to FIG. 9, a wet etching process and a washing process can be simultaneously performed with respect to the resultant structure. Accordingly, the top surface of the floating gate 55 is formed having concave-convex shapes. The concave-convex shape represents that the surface of the floating gate 55 is rough.

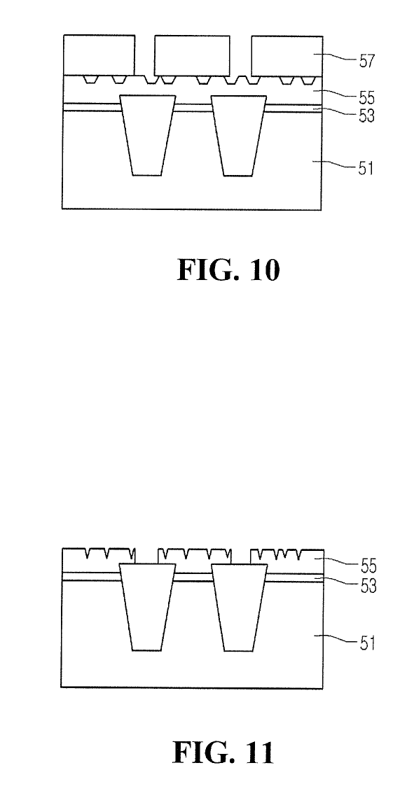

Then, as shown in FIGS. 10 to 12, the floating gate 55 can be patterned by using the patterned photoresist 57, and an ONO layer 61 can be deposited on the patterned floating gate 55. Subsequently, a control gate 63 can be formed on the ONO layer 61. Then, spacers 65 are formed at the sidewalls of the control gate 63, the ONO layer 61, and the floating gate 55.

The ONO layer 61 may be formed through a deposition scheme, so that the top and bottom surfaces of the ONO layer 61 may be formed following the concave-convex shapes of the floating gate 55. In addition, the control gate 63 may be formed through a deposition scheme, and the bottom surface of the control gate 63 may be formed in the concave-convex shapes. Accordingly, the surface area may be widened.

The semiconductor device obtained according to the above method for fabricating the semiconductor device includes the tunnel oxide layer 53 formed on the semiconductor substrate 51, the floating gate 55 formed on the tunnel oxide layer 53 and having the concave-convex shapes, the ONO layer 61 formed on the floating gate 55, and the control gate 63 formed on the ONO layer 61.

The semiconductor device having the above structure increases a control-floating coupling coefficient, so that the semiconductor device can be manufactured in a small size, and device characteristics thereof can be improved.

As described above, in the semiconductor device and the method for fabricating the same, the control-floating gate coefficient is increased, so that the semiconductor device can be manufactured in a small size, and device characteristics thereof may be improved.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a tunnel oxide layer on a semiconductor substrate;
a floating gate on the tunnel oxide layer, wherein the top surface of the floating gate has a concave-convex shape;
an ONO (oxide/nitride/oxide) layer on the floating gate; and
a control gate on the ONO layer.

2. The semiconductor device according to claim 1, wherein the ONO layer has top and bottom surfaces following the concave-convex shape.

3. The semiconductor device according to claim 1, wherein the control gate has a bottom surface following the concave-convex shape.

4. The semiconductor device according to claim 1, further comprising spacers formed at sidewalls of the control gate, the ONO layer, and the floating gate.

5. The semiconductor device according to claim 1, wherein the concave-convex shape comprises a rough pattern of protruding and recessed portions.

6. A method for fabricating a semiconductor device, comprising:
forming a tunnel oxide layer on a semiconductor substrate;
depositing polysilicon on the tunnel oxide layer;
etching the polysilicon using a photoresist pattern to form a floating gate;
performing an under ashing process with respect to the photoresist pattern such that a residue remains at an upper portion of the floating gate;
performing a blank etching process using the residue as a mask to form concave-convex shapes on the top surface of the floating gate;
depositing an ONO (oxide/nitride/oxide) layer on the floating gate having the concave-convex shapes; and
forming a control gate on the ONO layer.

7. The method according to claim 6, wherein the ONO layer has top and bottom surfaces following the concave-convex shapes.

8. The method according to claim 6, wherein the control gate has a bottom surface following the concave-convex shapes.

9. The method according to claim 6, further comprising forming spacers at sidewalls of the control gate, the ONO layer, and the floating gate.

10. The method according to claim 6, wherein forming the control gate comprises performing a deposition scheme.

11. The method according to claim 6, wherein the concave-convex shapes comprise a rough pattern of protruding and recessed portions.

12. A method for fabricating a semiconductor device, comprising:
forming a tunnel oxide layer on a semiconductor substrate;
forming a floating gate layer on the tunnel oxide layer;
performing a blank etching process with respect to the floating gate layer to partially damage a top surface of the floating gate layer and form a residue on regions of the floating gate layers;
performing a wet etching process and a washing process to remove the residue, thereby forming concave-convex shapes on the top surface of the floating gate layer;
patterning the floating gate layer having the concave-convex shapes into a floating gate;
depositing an ONO (oxide/nitride/oxide) layer on the floating gate; and
forming a control gate on the ONO layer.

13. The method according to claim 12, wherein the ONO layer has top and bottom surfaces following the concave-convex shapes.

14. The method according to claim 12, wherein the control gate has a bottom surface following the concave-convex shapes.

15. The method according to claim 12, further comprising forming spacers at sidewalls of the control gate, the ONO layer, and the floating gate.

16. The method according to claim 12, wherein forming the control gate comprises performing a deposition scheme.

17. The method according to claim 12, wherein the concave-convex shapes comprise a rough pattern of protruding and recessed portions.
